(19) United States
(12) Patent Application Publication
(10) Pub. No.: US 2025/0133872 A1
(43) Pub. Date: Apr. 24, 2025

(54) EPITAXIAL STRUCTURE AND METHOD OF MANUFACTURING THE SAME AND LIGHT EMITTING DIODE

(71) Applicant: Quanzhou sanan semiconductor technology Co., Ltd., Fujian (CN)

(72) Inventors: Yanbin FENG, Fujian (CN); Wenhao GAO, Fujian (CN); Chaoyu WU, Fujian (CN); Qian LIANG, Fujian (CN)

(73) Assignee: Quanzhou sanan semiconductor technology Co., Ltd., Fujian (CN)

(21) Appl. No.: 18/915,310

(22) Filed: Oct. 14, 2024

(30) Foreign Application Priority Data
Oct. 19, 2023 (CN) 202311358047.0

(51) Int. Cl. H01L 33/12; H01L 33/00; H01L 33/06; H01L 33/30

(52) U.S. Cl. CPC H10H 20/815; H10H 20/013; H10H 20/812; H10H 20/824

(57) ABSTRACT

An epitaxial structure, a light emitting diode (LED), and a method of manufacturing the epitaxial structure are provided. The epitaxial structure includes a P-type semiconductor layer, a light emitting region, and a N-type semiconductor layer stacked in sequence. A thickness of the P-type semiconductor layer 110 is less than or equal to 1.0 μm. By limiting the overall thickness of the P-type semiconductor layer, the internal stress and the internal stress distribution of each sublayer are optimized. Stress accumulation is effectively reduced, and structural defects of the light emitting diode caused by stress release during packaging and use are reduced or eliminated. The light emitting brightness of the light emitting diode is thereby improved, and the service life of the light emitting diode is prolonged.

### CROSS-REFERENCE TO RELATED APPLICATION

This application claims the priority benefit of China application serial no. 202311358047.0, filed on Oct. 19, 2023. The entirety of the above-mentioned patent application is hereby incorporated by reference herein and made a part of this specification.

### BACKGROUND

### Technical Field

The disclosure relates to the semiconductor field, and in particular, relates to an epitaxial structure, a method of manufacturing the same, and a light emitting diode (LED).

### Description of Related Art

A light emitting diode is a semiconductor device, and its basic structure includes a PN junction between P-type semiconductor and N-type semiconductor. When a forward voltage is applied to the LED, electrons and holes recombine at the interface of the PN junction, releasing energy. This energy is emitted in the form of photons and forms light radiation.

For GaAs-based near-infrared light emitting diodes, the light emitting wavelength ranges from 780 nm to 1,200 nm. Their epitaxial structure's N-type and P-type window layer materials are AlₓGa₁₋ₓAs materials with different compositions. The light emitting region adopts a composite quantum well structure, where the quantum well material uses the InGaAs material. Therefore, significant stress is provided among the cladding layer, window layer, and the light emitting region. Further, compressive stress is provided between the epitaxial structure and the GaAs substrate. When the stress accumulation in the structure reaches a specific level, material defects will occur, thereby introducing lattice mismatch defects into the structure.

This light emitting diode structure with internal stress and structural defects will continue to introduce new stress in subsequent chip packaging processes, and the release of internal stress in the chip is thus accelerated. This leads to shortened service life of the packaged chip or even inability to emit light, so the product yield is considerably affected.

### SUMMARY

The disclosure aims to solve one or more of the abovementioned problems.

In the first aspect, the disclosure provides an epitaxial structure having a first surface and a second surface opposite to each other, a direction from the first surface to the second surface is a first direction, and the epitaxial structure includes a P-type semiconductor layer, a light emitting region, and an N-type semiconductor layer stacked in sequence in the first direction.

The P-type semiconductor layer at least includes a first ohmic contact layer, a first window layer, and a first cladding layer in sequence in the first direction.

The light emitting region includes an active layer formed by stacking quantum well layers and quantum barrier layers in an alternating manner.

The N-type semiconductor layer at least includes a second cladding layer, a second window layer, and a second ohmic contact layer in the first direction.

A thickness of the P-type semiconductor layer is less than or equal to 1.0 μm.

In the second aspect, the disclosure further provides a light emitting diode (LED) including the epitaxial structure provided by the above technical solution.

In the third aspect, the disclosure further provides a method of manufacturing an epitaxial structure. The method includes the following steps.

A growth substrate is provided.

A second ohmic contact layer is formed on the growth substrate.

A second window layer having a thickness less than or equal to 8.0 μm is grown on the second ohmic contact layer.

A second cladding layer having a thickness less than or equal to 0.4 μm is grown on the second window layer.

A light emitting region including a second spacer layer, an active layer, and a first spacer layer stacked in sequence and having a thickness ranging from 1.0 μm to 2.0 μm is grown on the second cladding layer.

A first cladding layer having a thickness less than or equal to 0.4 μm is grown on the light emitting region.

A first window layer having a thickness less than or equal to 0.5 μm is grown on the first cladding layer.

A first ohmic contact layer having a thickness less than or equal to 0.1 μm is grown on the first window layer.

Compared to the related art, beneficial effects produced by the technical solution of the disclosure include the following.

In the technical solution provided by the disclosure, while ensuring that the P-type semiconductor layer is able to provide sufficient carrier holes, the overall thickness of the P-type semiconductor layer is reduced. Further, by limiting the thickness range or relative thickness ratio of each functional sublayer in the P-type semiconductor layer, the internal stress and internal stress distribution of each sublayer are optimized, and the bonding performance between each sublayer is also improved. This reduces subsequent stress accumulation during the growth process of the sublayers, resulting in higher structural strength for the semiconductor epitaxial structure, and the packaging quality is also improved. In addition, in the epitaxial structure provided by the disclosure, especially for a GaAs-based near-infrared light emitting diode, the large internal stress caused by the different lattice parameters of the epitaxial structure and the quantum well layers is reduced, and the defects of the infrared light emitting diode caused by stress release during high-stress packaging and use are decreased or eliminated. Moreover, the thinner epitaxial structure also brings lower light absorption loss, the electro-optical conversion efficiency and light emitting brightness of the infrared light emitting diode are thereby enhanced, and the device's service life is prolonged.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view of an epitaxial structure according to Embodiment 1 of the disclosure.

FIG. 2 is a schematic structural view of a light emitting diode (LED) according to Embodiment 2 of the disclosure.

FIG. 3 is a flow chart of a method of manufacturing the epitaxial structure according to Embodiment 3 of the disclosure.

### DESCRIPTION OF THE EMBODIMENTS

### Embodiment 1

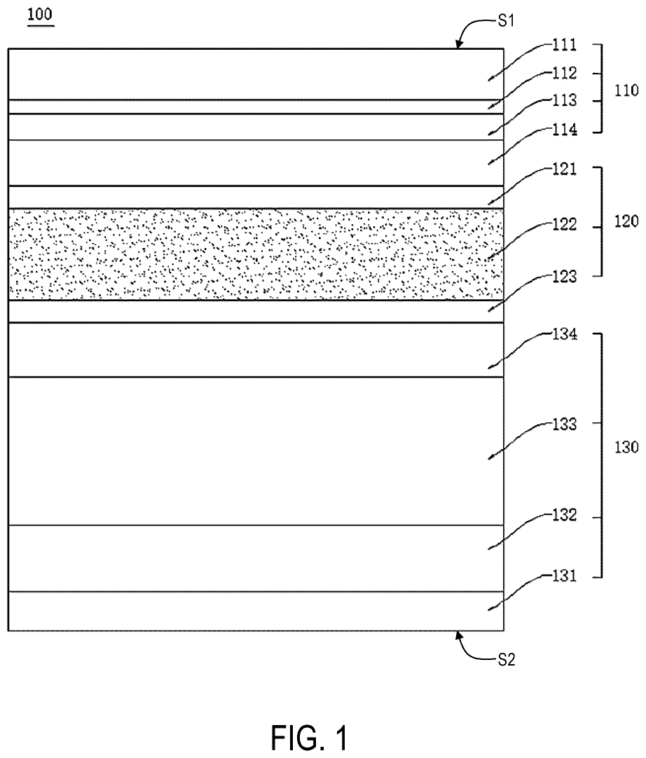

This embodiment provides an epitaxial structure 100, and as shown in FIG. 1, the epitaxial structure 100 has a first surface S1 and a second surface S2 opposite to each other, a direction from the first surface S1 to the second surface S2 is a first direction, and the epitaxial structure 100 includes a P-type semiconductor layer 110, a light emitting region 120, and an N-type semiconductor layer 130 stacked in sequence in the first direction.

The P-type semiconductor layer 110 at least includes a first ohmic contact layer 111, a first window layer 113, and a first cladding layer 114 in sequence in the first direction.

The light emitting region 120 includes an active layer 122 formed by stacking quantum well layers and quantum barrier layers in an alternating manner.

The N-type semiconductor layer 130 at least includes a second cladding layer 134, a second window layer 133, and a second ohmic contact layer 131 in the first direction.

A thickness of the P-type semiconductor layer 110 is less than or equal to 1.0 μm.

In this embodiment, the overall thickness of the P-type semiconductor layer 110 is defined. On the basis of ensuring that the P-type semiconductor layer 110 can provide sufficient holes (carriers), the overall thickness of the P-type semiconductor layer 110 is reduced, and an overall thickness of the epitaxial structure 100 is further reduced while thicknesses of the light emitting region 120 and the N-type semiconductor layer 130 remain unchanged. Since the P-type semiconductor layer 110 includes a plurality of functional sublayers, the predetermined P-type semiconductor layer 110 with an optimized thickness is obtained by limiting the thickness of at least one sublayer. By limiting the thickness range or relative thickness ratio of each functional sublayer contained in the P-type semiconductor layer 110, the internal stress and internal stress distribution of each sublayer are optimized, and the bonding performance between each sublayer is also improved. This reduces subsequent stress accumulation during the growth process of these sublayers, resulting in higher structural strength for both the P-type semiconductor layer 110 and the semiconductor epitaxial structure 100, and the product packaging quality is also improved.

In this embodiment, taking the epitaxial structure 100 with a light emitting wavelength range of 780 nm to 1200 nm near-infrared light as an example, the active layer 122 is a composite quantum well structure formed by stacking quantum well layers and quantum barrier layers in an alternating manner. A material of the quantum well layers is InGaAs, and a material of the quantum barrier layers is AlGaAsP. A number of times of the reappearance of the aforementioned alternately stacked structure (a number of periods of the active layer 122) is 4 to 20. By adjusting the composition ratio of semiconductor materials in the active layer 122, light with the target wavelength is emitted.

To be specific, in the exemplified epitaxial structure 100, a material of the first window layer 113 is P-type doped AlₓGa₁₋ₓAs, and a material of the second window layer 133 is N-type doped Al_{y}Ga_{1-y}As, where (0≤x,y≤0.4) and x≠y. That is, the materials of the two window layers on the upper and lower surfaces of the light emitting region 120 are the same but with different compositions. The N-type doped second window layer 133 and the P-type doped first window layer 113 serve to distribute and diffuse the current uniformly, which may enhance light extraction efficiency. As an example, the first window layer 113 may be a C-doped AlGaAs material, and the second window layer 133 may be a Te-doped AlGaAs material. However, due to the difference in lattice constants between the AlₓGa₁₋ₓAs material and the InGaAs material, the internal stress caused by lattice mismatch is generated among the first window layer 113, the second window layer 133, and the active layer 122. The thicker each functional layer is, the greater the accumulated internal stress, and the greater the impact on subsequent packaging and the entire epitaxial structure. In addition to controlling the overall thickness of the P-type semiconductor layer 110, a thickness of the first window layer 113 is specially defined to reduce its deposition thickness while balancing its current diffusion function and structural stability.

In an embodiment, the thickness of the first window layer 113 is less than or equal to 0.5 μm. This balances the reduced current diffusion capability due to the decreased thickness of the first window layer 113 with the optimization of internal stress distribution.

In an embodiment, the thickness of the first window layer 113 is 0 to 0.3 μm. Based on the above technical solution, the thickness of the first window layer 113 is further controlled. Between the reduced current diffusion capability due to thinning the first window layer 113 and the issues of greater structural stress or uneven stress distribution caused by thinning the first window layer 113, priority is given to addressing the internal stress problem that has a more significant impact on device yield and service life. The first window layer 113 is further thinned to a thickness within 0.3 μm, which may greatly solve or eliminate the stress problem caused by lattice mismatch within the epitaxial structure.

In an embodiment, the thickness of the first window layer 113 is 0 μm. That is, the first window layer 113 is omitted, allowing a transition layer 112 or the first ohmic contact layer 111 to be in direct contact with the first cladding layer 114. By omitting the first window layer 113, the overall thickness of the P-type semiconductor layer 110 may be greatly reduced, resulting in less light absorption, which compensates for the negative impact on light emitting brightness due to reduced current diffusion capability. While the first window layer 113 is omitted, the internal stress of the P-type semiconductor layer 110 may also be significantly reduced, and product reliability is thus further enhanced. Therefore, in the epitaxial structure 100 provided in this embodiment, especially for a GaAs-based near-infrared light emitting diode (LED), a large number of defects caused by interface mismatch due to different lattice parameters of the epitaxial structure 100 and the quantum well layers can be effectively reduced, and the current blockage in the infrared light emitting diode is therefore decreased. Moreover, while the first window layer 113 is omitted, the thinner epitaxial structure 100 also brings lower light absorption loss, the electro-optical conversion efficiency and light emitting brightness of the light emitting diode are thereby enhanced, and the device's service life is prolonged. In addition, the material production costs of the epitaxial structure 100 may also be effectively controlled, and a large amount of material purchase cost is saved, which is more conducive to large-scale industrial promotion and use.

In an embodiment, the thickness of the epitaxial structure 100 is less than or equal to 10.5 μm. While satisfying process requirements and optical-electrical performance design requirements, the overall thickness of the epitaxial structure 100 is limited to reduce the internal stress of the epitaxial structure 100, ensuring that the accumulated internal stress of each layer and the total stress within do not exceed a critical value. Even if there is some lattice mismatch between layers, it may not cause substantial structural damage in subsequent packaging processes, and the reliability of the epitaxial structure 100 is thereby enhanced. As an example, the thickness of the epitaxial structure 100 may range from 8 μm to 10 μm. If the overall thickness of the epitaxial structure 100 is less than 8 μm, there may be charge transfer hindrance, and the functional layers may not fully exert their effects. Although stress is reduced, more performance indicators are sacrificed. If the overall thickness of the epitaxial structure 100 is greater than 10 μm, the improvement in charge transfer is not significant, but instead brings more risks of structural defects. Therefore, limiting the thickness of the epitaxial structure 100 to a reasonable range balances charge transfer efficiency, ensures structural strength, and reduces structural stress.

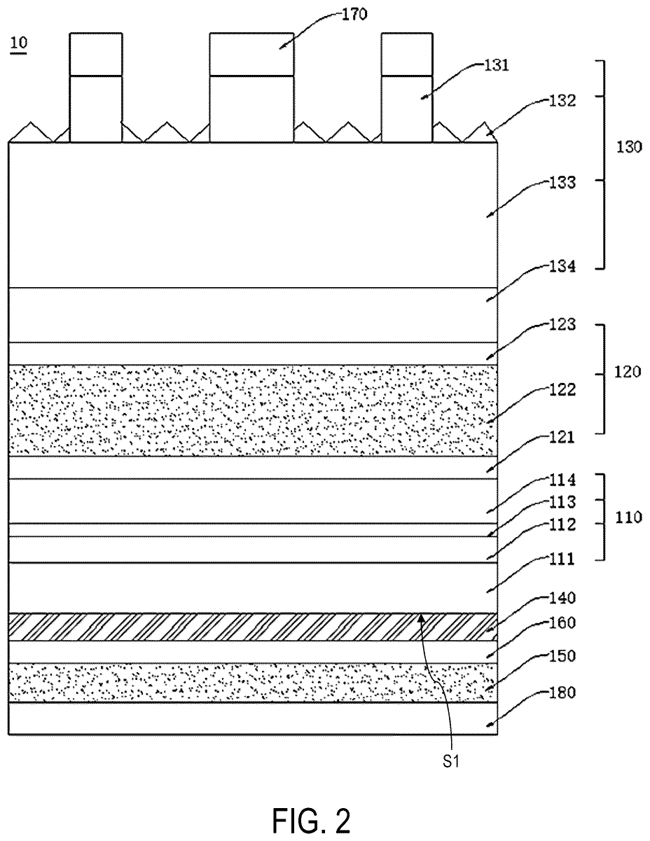

In an embodiment, a thickness of the first ohmic contact layer is less than or equal to 0.1 μm. The first ohmic contact layer 111 with this thickness has lower internal stress and better surface morphology, while ensuring good ohmic contact and current diffusion between the epitaxial structure 100 and a first electrode 170 (as shown in FIG. 2) to be described in the following paragraphs. As an example, the thickness of the first ohmic contact layer 111 may range from 0.04 μm to 0.06 μm. When the thickness of the first ohmic contact layer 111 is less than 0.1 μm, as the thickness decreases, its current diffusion performance decreases proportionally, while its structural performance and morphology quality improve. A thickness of 0.04 μm to 0.06 μm can ensure basic charge transport performance and better structural performance. When the thickness is less than 0.04 μm, its current diffusion capability decreases significantly, and the structural improvement benefits are not sufficient to compensate for the loss in electrical performance. As an example, the thickness of the first ohmic contact layer 111 is 0.05 μm. In this embodiment, the first ohmic contact layer 111 may be C-doped GaP.

In an embodiment, a thickness of the first cladding layer 114 is less than or equal to 0.4 μm. The first cladding layer 114 is made of a material with a smaller band gap, which can adjust the propagation direction of light, improve the output power of the semiconductor, and optimize the performance and stability of the semiconductor. The material of the first cladding layer 114 may be C-doped AlGaAs. Further, the thickness of the first cladding layer 114 is 0.30 μm to 0.38 μm. The first cladding layer 114 within this thickness range has a relatively small internal stress and has sufficient thickness to ensure sufficient carrier supply.

In an embodiment, the light emitting region 120 includes a first spacer layer 121 located between the active layer 122 and the P-type semiconductor layer 110. The first spacer layer 121 uses an undoped AlGaAs material, which can prevent P-type dopants from diffusing into the active layer 122. The first spacer layer 121 may adopt a single-layer or multi-layer structure and provides lattice mismatch transition between the P-type semiconductor layer 110 and the active layer 122, so that the crystal quality of the active layer is enhanced and the brightness of the light emitting diode is improved.

In an embodiment, a thickness of the second cladding layer 134 is less than or equal to 0.4 μm. A material of the second cladding layer 134 may be Te-doped AlGaAs. Further, the thickness of the second cladding layer 134 is 0.30 μm to 0.38 μm. Similar to the principle of the first cladding layer 114, the second cladding layer 134 at this thickness also has a smaller internal stress and has sufficient thickness to ensure sufficient carrier supply, and the light absorption effect is relatively reduced.

In an embodiment, the light emitting region 120 includes a second spacer layer 123 located between the active layer 122 and the N-type semiconductor layer 130. The second spacer layer 123 may also use an undoped AlGaAs material. Similar to the principle of the first spacer layer 121, the second spacer layer 123 can prevent N-type dopants from diffusing into the active layer 122. The second spacer layer 123 may adopt a single-layer or multi-layer structure as well and provides lattice mismatch transition between the N-type semiconductor layer 130 and the active layer 122, so that the crystal quality of the active layer is enhanced and the brightness of the light emitting diode is improved.

In an embodiment, the thickness of the light emitting region 120 ranges from 1.0 μm to 2.0 μm, and the light emitting region 120 includes the active layer 122 and the first spacer layer 121 and the second spacer layer 123 adjacent to the upper and lower sides of the active layer 122. As an example, the overall thickness of the light emitting region 120 ranges from 1.2 μm to 1.8 μm. By limiting the overall thickness of the light emitting region 120, the total internal stress magnitude of the light emitting region 120 is controlled, and a sufficient thickness maintained, so that sufficient carrier recombination is ensured.

In an embodiment, while the first window layer 113 is omitted, the thickness of the light emitting region 120 is controlled to be in the range of 1.0 μm to 2.0 μm and the thickness of the active layer 122 is controlled to be in the range of 0.4 μm to 1.6 μm, so as to compensate for the significant reduction in current diffusion capability and loss of electrical performance due to the lack of the first window layer 113.

In some embodiments, the P-type semiconductor layer 110 further includes the transition layer 112 located between the first ohmic contact layer 111 and the first window layer 113. The transition layer 112 is a Zn-doped GaInP material and used to connect the first ohmic contact layer 111 and the first window layer 113, so that the crystal quality of the epitaxial structure 100 may be enhanced to some extent. When the first window layer 113 is entirely omitted, the transition layer 112 is located between the first ohmic contact layer 111 and the first cladding layer 114. Due to a relatively thin thickness of the transition layer 112, without significantly increasing the thickness of the epitaxial structure 100, the transition layer 112 serves to effectively bond the two functional layers above and below it and reduces the interface stress brought by direct contact between the two functional layers above and below it. As an example, the thickness of the transition layer 112 is 0.02 μm to 0.04 μm. As an example, the thickness of the transition layer 112 is 0.03 μm.

In some embodiments, the N-type semiconductor layer 130 further includes an etching stop layer 132 located between the second ohmic contact layer 131 and the second window layer 133. A material of the etching stop layer 132 for subsequent chemical etching steps is n-GaInP, which facilitates the subsequent removal of a growth substrate 200, ensuring that the removal process does not cause damage to the epitaxial structure 100. As an example, a thickness of the etching stop layer 132 is less than or equal to 0.2 μm. As an example, the thickness of the etching stop layer 132 is 0.1 μm.

In an embodiment, a thickness of the second window layer 133 is less than or equal to 8.0 μm. The material of the second window layer 133 may be Te-doped AlGaAs with a composition different from that of the second cladding layer 134, so as to obtain improved current diffusion capability. Further, the thickness of the second window layer 133 is 6.5 μm to 7.5 μm. Since the current diffusion capability of the second window layer 133 has a closer relationship with its thickness, when regulating its internal stress magnitude by limiting the thickness of the second window layer 133, the thickness that can be reduced is limited under the condition of ensuring electrical performance. As an example, the thickness of the second window layer 133 is 7.0 μm. Maintaining the thickness of the second window layer 133 can be used together with a roughening process and ensure current diffusion uniformity.

### Embodiment 2

With reference to FIG. 2, in this embodiment, a light emitting diode 10 including any epitaxial structure 100 as described in Embodiment 1 is provided.

To be specific, in this embodiment, the light emitting diode 10 further include a reflective structure 140 located on the first surface S1 of the epitaxial structure 100. In a direction opposite to the first direction, a bonding layer 160 and a substrate 150 are sequentially stacked on top of the reflective structure 140, where the bonding layer 160 may be a metal material layer, an alloy layer, or a semiconductor material layer. In this embodiment, a metal material layer is preferred, which may be, for example, Cu, Al, Sn, Au, Ag, Pb, Ti, Ni, In, Pt, or W.

To be specific, the light emitting diode 10 may further include an electrode structure including the first electrode 170 formed on the N-type semiconductor layer 130 and electrically connected to the N-type semiconductor layer 130 and a second electrode 180 formed on the substrate 150 and electrically connected to the P-type semiconductor layer 110. The second electrode 180 may be a metal layer on a surface of the substrate 150.

To be specific, the light emitting diode 10 is a near-infrared diode, with an emission wavelength ranges from 780 nm to 1200 nm.

Since each functional layer of the epitaxial structure 100 provided in Embodiment 1 has a relatively small and uniformly distributed internal stress, the semiconductor epitaxial structure 100 as a whole has higher structural strength and stability. The large internal stress caused by the different lattice parameters of the epitaxial structure 100 and the quantum well layers is reduced, and the defects of the infrared light emitting diode caused by stress release during high-stress packaging and use are decreased or eliminated. Further, a thinner epitaxial structure 100 also results in lower light absorption loss, so the light emitting diode 10 of the epitaxial structure 100 provided in Embodiment 1 also has improved light emitting brightness and quality reliability.

The performance of the light emitting diode provided in this embodiment is tested, and the test results are shown in Table 1 below.

TABLE 1
Comparison of LED performance between related art and the disclosure

| | VF | WLP | LOP | Light decay duration (%) | | | | | | | |
|---|---|---|---|---|---|---|---|---|---|---|---|
| | (V) | (nm) | (mv) | 0 | 96 | 168 | 336 | 504 | 672 | 840 | 1008 |
| LED of | 1.351 | 943.1 | 45.88 | 100.00 | 96.8 | 96.45 | 95.05 | 93.66 | 92.57 | 91.32 | 91.07 |
| related art | | | | | | | | | | | |
| LED | 1.349 | 942.4 | 47.45 | 100.00 | 99.68 | 100.12 | 100.19 | 100.15 | 100.01 | 99.68 | 99.38 |
| of the | | | | | | | | | | | |
| disclosure | | | | | | | | | | | |

It can be seen from the data in the above table that in the disclosure, by limiting the overall thickness of the P-type semiconductor layer 110, in particular, after the first window layer 113 is thinned, the large internal stress caused by the different lattice parameters of the epitaxial structure 100 and the quantum well layers is reduced, and the defects of the infrared light emitting diode caused by stress release during high-stress packaging and use are reduced or eliminated. Moreover, the thinner epitaxial structure 100 also brings lower light absorption loss, the electro-optical conversion efficiency and light emitting brightness of the light emitting diode 10 are thereby comprehensively enhanced, and the device's service life is prolonged.

### Embodiment 3

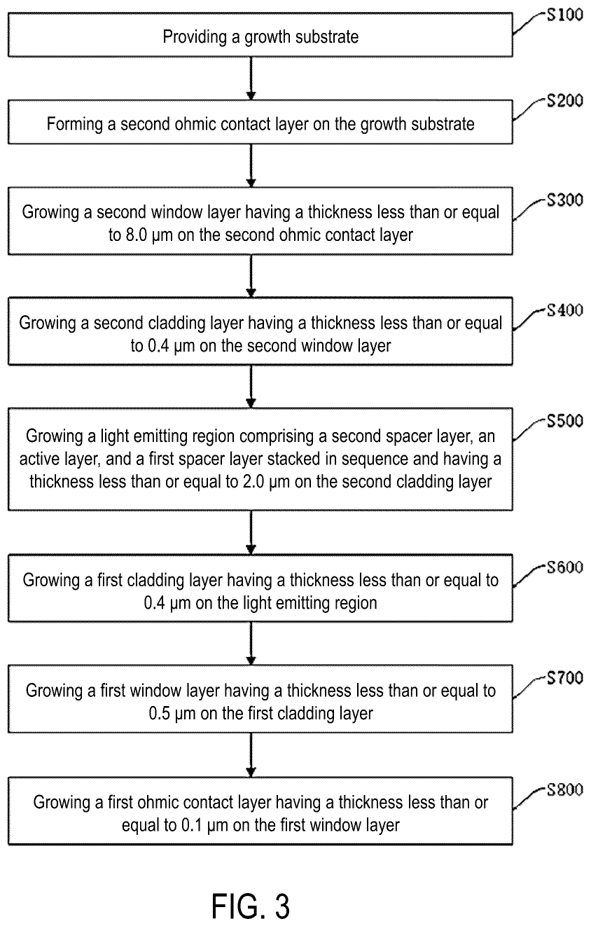

With reference to FIG. 1 and FIG. 3, the disclosure further provides a method of manufacturing an epitaxial structure, and the following steps are included.

In S100, a growth substrate is provided.

To be specific, the growth substrate may be any substrate suitable for epitaxy, such as a Si substrate, a SiC substrate, a sapphire substrate, a GaAs substrate, etc. In this example, a GaAs substrate is used.

In S200, the second ohmic contact layer 131 having a thickness less than or equal to 0.1 μm (e.g., may be 0.04 μm to 0.06 μm) is formed on the growth substrate.

To be specific, the material of the second ohmic contact layer 131 may be GaAs.

In S300, the second window layer 133 having a thickness less than or equal to 8.0 μm (e.g., may be 6.5 μm to 7.5 μm) is formed on the second ohmic contact layer 131. The thickness of the second window layer 133 is defined during the process to control its internal stress magnitude. A second window layer 133 with a sufficient thickness can be combined with a roughening process and ensure current diffusion uniformity.

In S400, the second cladding layer 134 having a thickness less than or equal to 0.4 μm (e.g., may be 0.30 μm to 0.38 μm) is formed on the second window layer 133. The material of the second cladding layer 134 may be Te-doped AlGaAs. The second cladding layer 134 with this thickness has a relatively small internal stress, and the light absorption effect is also relatively lowered. A second cladding layer 134 with a sufficient thickness can ensure sufficient carrier supply. To be specific, the material of the second cladding layer 134 may be Te-doped AlGaAs.

In S500, the light emitting region 120 including the second spacer layer 123, the active layer 122, and the first spacer layer 121 stacked in sequence is grown on the second cladding layer 134. Taking the epitaxial structure 100 with a light emitting wavelength range of 780 nm to 1200 nm near-infrared light as an example, the active layer 122 is a composite quantum well structure formed by stacking quantum well layers and quantum barrier layers in an alternating manner. The material of the quantum well layers is InGaAs, and the material of the quantum barrier layers is AlGaAsP. A number of times of the reappearance of the aforementioned alternately stacked structure (a number of periods of the active layer 122) is 4 to 20. By adjusting the composition ratio of semiconductor materials in the active layer 122, light with the target wavelength may be emitted. The thickness of the light emitting region 120 ranges from 1.0 μm to 2.0 μm, for example, the overall thickness of the light emitting region 120 may range from 1.2 μm to 1.8 μm. By limiting the overall thickness of the light emitting region 120, the total internal stress magnitude of the light emitting region 120 is controlled. Meanwhile, the light emitting region 120 with a sufficient thickness can ensure sufficient recombination of carriers (holes) and electrons.

In S600, the first cladding layer 114 having a thickness less than or equal to 0.4 μm (e.g., may be 0.30 μm to 0.38 μm) is formed on the light emitting region 120. The first cladding layer 114 is made of a material with a smaller band gap, which can adjust the propagation direction of light, improve the output power of the semiconductor, and optimize the performance and stability of the semiconductor. The material of the first cladding layer 114 may be C-doped AlGaAs.

Similar to the principle of the second cladding layer 134, the first cladding layer 114 within this thickness range has a relatively small internal stress. Further, the first cladding layer 114 with a sufficient thickness can ensure sufficient carrier supply.

In S700, the first window layer 113 having a thickness less than or equal to 0.5 μm is grown on the first cladding layer 114. To be specific, the material of the first window layer 113 may be C-doped AlGaAs.

In S800, the first ohmic contact layer 111 having a thickness less than or equal to 0.1 μm (e.g., may be 0.04 μm to 0.06 μm) is grown on the first window layer 113. The first ohmic contact layer 111 with this thickness has lower internal stress and better surface morphology, while ensuring good ohmic contact and current diffusion between the epitaxial structure 100 and the first electrode 170 to be bonded in subsequent processes. To be specific, the material of the first ohmic contact layer 111 may be C-doped GaP.

By adopting the above technical solution, the N-type semiconductor layer 130, the light emitting region 120, and the P-type semiconductor layer 110 with limited thickness ranges are formed on the growth substrate in sequence, the internal stress and internal stress distribution of each sublayer are controlled, and the bonding performance between each sublayer is improved. The appropriate layer thickness also reduces the epitaxial structure's absorption of light, so the light emitting brightness is increased. In addition, the material production costs of the epitaxial structure 100 may also be effectively controlled, which is more conducive to large-scale industrial promotion and use.

In an embodiment, the method of manufacturing the epitaxial structure 100 further includes the following step.

Before the second window layer 133 is grown, the etching stop layer 132 is grown on the second ohmic contact layer 131. The etching stop layer 132 is located between the second ohmic contact layer 131 and the second window layer 133. The material of the etching stop layer 132 for the subsequent chemical etching step is n-GaInP, which facilitates the subsequent removal of the growth substrate without causing damage to the epitaxial structure 100 during the process of removing the growth substrate. The thickness of the etching stop layer 132 is less than or equal to 0.2 μm, for example, the thickness of the etching stop layer 132 may be 0.1 μm.

In an embodiment, the method of manufacturing the epitaxial structure 100 does not include the step of growing the first window layer 113, that is, the transition layer 112 is directly grown on the surface of the first cladding layer 114. By omitting the first window layer 113, the overall thickness of the P-type semiconductor layer may be greatly reduced, resulting in less light absorption and significantly reduced internal stress, so that the reliability of the device is further improved.

In an embodiment, the method of manufacturing the epitaxial structure 100 further includes the following step.

Before the first ohmic contact layer 111 is grown, the transition layer 112 is grown on the first cladding layer 114, where the transition layer 112 is located between the first cladding layer 114 and the first ohmic contact layer 111. The transition layer 112 is a Zn-doped GaInP material and used to connect the first ohmic contact layer 111 and the first cladding layer 114, so that the crystal quality of the epitaxial structure is enhanced to some extent. The thickness of the transition layer 112 is 0.02 μm to 0.04 μm, for example, the thickness of the transition layer 112 may be 0.03 μm.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An epitaxial structure having a first surface and a second surface opposite to each other, a direction from the first surface to the second surface being a first direction, and the epitaxial structure comprising a P-type semiconductor layer, a light emitting region, and an N-type semiconductor layer stacked in sequence in the first direction, wherein
the P-type semiconductor layer at least comprises a first ohmic contact layer, a first window layer, and a first cladding layer in sequence in the first direction,
the light emitting region comprises an active layer formed by stacking quantum well layers and quantum barrier layers in an alternating manner, and
the N-type semiconductor layer at least comprises a second cladding layer, a second window layer, and a second ohmic contact layer in the first direction,
wherein a thickness of the P-type semiconductor layer is less than or equal to 1.0 μm.

2. The epitaxial structure according to claim 1, wherein a thickness of the epitaxial structure is less than or equal to 10.5 μm.

3. The epitaxial structure according to claim 2, wherein the thickness of the epitaxial structure ranges from 8 μm to 10 μm.

4. The epitaxial structure according to claim 1, wherein a thickness of the first ohmic contact layer is less than or equal to 0.1 μm.

5. The epitaxial structure according to claim 1, wherein a thickness of the first cladding layer is less than or equal to 0.4 μm.

6. The epitaxial structure according to claim 1, wherein a thickness of the second cladding layer is less than or equal to 0.4 μm.

7. The epitaxial structure according to claim 1, wherein a thickness of the light emitting region ranges from 1.0 μm to 2.0 μm.

8. The epitaxial structure according to claim 1, wherein the P-type semiconductor layer further comprises a transition layer located between the first ohmic contact layer and the first window layer.

9. The epitaxial structure according to claim 1, wherein a thickness of the first window layer is less than or equal to 0.5 μm.

10. The epitaxial structure according to claim 1, wherein the N-type semiconductor layer further comprises an etching stop layer located between the second ohmic contact layer and the second window layer.

11. The epitaxial structure according to claim 1, wherein a material of the first window layer is P-type doped AlₓGa₁₋ₓAs, and a material of the second window layer is N-type doped Al_{y}Ga_{1-y}As, wherein (0≤x, y≤0.4) and x≠y.

12. The epitaxial structure according to claim 1, wherein a material of the quantum well layers is InGaAs.

13. The epitaxial structure according to claim 12, wherein a number of periods of the active layer is 4 to 20.

14. A light emitting diode (LED) comprising the epitaxial structure according to claim 1.

15. A method of manufacturing an epitaxial structure, comprising:
providing a growth substrate;
forming a second ohmic contact layer on the growth substrate;
growing a second window layer having a thickness less than or equal to 8.0 μm on the second ohmic contact layer;
growing a second cladding layer having a thickness less than or equal to 0.4 μm on the second window layer;
growing a light emitting region comprising a second spacer layer, an active layer, and a first spacer layer stacked in sequence and having a thickness ranging from 1.0 μm to 2.0 μm on the second cladding layer;
growing a first cladding layer having a thickness less than or equal to 0.4 μm on the light emitting region;
growing a first window layer having a thickness less than or equal to 0.5 μm on the first cladding layer;
growing a first ohmic contact layer having a thickness less than or equal to 0.1 μm on the first window layer.

16. The method of manufacturing the epitaxial structure according to claim 15, further comprising:
growing an etching stop layer on the second ohmic contact layer before growing the second window layer, wherein the etching stop layer is located between the second ohmic contact layer and the second window layer.

17. The method of manufacturing the epitaxial structure according to claim 15, further comprising:
growing a transition layer on the first cladding layer before growing the first ohmic contact layer, wherein the transition layer is located between the first cladding layer and the first ohmic contact layer.
